(19) United States
(12) Patent Application Publication
(10) Pub. No.: US 2024/0213134 A1
(43) Pub. Date: Jun. 27, 2024

(54) ELECTRONIC PACKAGE

(71) Applicant: SILICONWARE PRECISION INDUSTRIES CO., LTD., Taichung (TW)

(72) Inventors: Chih-Hsien CHIU, Taichung (TW); Wen-Jung TSAI, Taichung (TW); Wei-Hao LI, Taichung (TW); Chih-Yi LIAO, Taichung (TW); Cheng-Wei HSU, Taichung (TW); Chih-Yuan TSAI, Taichung (TW); Ko-Wei CHANG, Taichung (TW); Guo-Yu WU, Taichung (TW)

(73) Assignee: SILICONWARE PRECISION INDUSTRIES CO., LTD., Taichung (TW)

(21) Appl. No.: 18/309,768

(22) Filed: Apr. 28, 2023

(30) Foreign Application Priority Data
Dec. 23, 2022 (TW) 111149798

(51) Int. Cl. H01L 23/498; H01L 23/31; H01L 25/10; H01L 25/16

(52) U.S. Cl. CPC H01L 23/49838; H01L 23/3128; H01L 23/315; H01L 23/49816; H01L 25/105; H01L 25/165; H01L 24/16; H01L 2225/107

(57) ABSTRACT

An electronic package is provided, in which an electronic element is disposed on a carrier with a circuit layer, and an encapsulation layer encapsulating the electronic element has an opening exposing the circuit layer, where a metal structure can be contact-bonded on a wall surface of the opening, and a conductive element is formed on the metal structure and electrically connected to the circuit layer. Therefore, no gap is formed between the conductive element and the wall surface of the opening, such that the DC resistance of the conductive element can be reduced.

### BACKGROUND

### 1. Technical Field

The present disclosure relates to a semiconductor device, and more particularly, to an electronic package that can improve electrical performance.

### 2. Description of Related Art

With the vigorous development of portable electronic products in recent years, the development of various related products is also moving towards the trends of high density, high performance, light, thin, short, and small. Therefore, various semiconductor packaging structures are also being innovated, in order to meet the requirements of thin, short and high density.

FIG. 1 is a schematic cross-sectional view of a conventional semiconductor package 1. As shown in FIG. 1, the semiconductor package 1 is provided with semiconductor elements 11 disposed on upper and lower sides of a packaging substrate 10, and then the semiconductor elements 11 are covered with an encapsulant 14, and a plurality of contacts (I/O) 100 of the packaging substrate 10 are exposed from openings 140 of the encapsulant 14, and then a plurality of solder balls 13 are formed on the contacts 100, so that in the subsequent process, the semiconductor package 1 can be connected to an electronic device such as a circuit board (not shown) via the solder balls 13.

Since the solder balls 13 will generate cohesive force, the solder balls 13 will become spherical after melting, and thus the entire laser-fired opening 140 is usually not filled by the solder material, so that a gap t will be generated between the solder ball 13 and the wall of the opening 140.

However, in the conventional semiconductor package 1, based on the electrical theory, the direct current resistance (DCR) of the conductive structure (such as the solder balls 13) in the encapsulant 14 is inversely proportional to the area of the conductive structure, so that the gap t caused by the cohesive force of the solder ball 13 tends to increase the DCR of the solder ball 13, thereby affecting the electrical (or telecommunication) performance. Therefore, there is a need for a solution that addresses the aforementioned shortcomings in the prior art.

### SUMMARY

In view of the aforementioned shortcomings of the prior art, the present disclosure provides an electronic package, which comprises: a carrier having a circuit layer, a first side and a second side opposing the first side; a second electronic element disposed on the second side of the carrier and electrically connected to the circuit layer; an encapsulation layer formed on the second side of the carrier and covering the second electronic element, wherein the encapsulation layer has at least one opening exposing part of the circuit layer; a metal structure contact-bonded on a wall surface of the opening; and a conductive element formed on the metal structure and electrically connected to the circuit layer.

In the aforementioned electronic package, the carrier is a packaging substrate with a core layer and a circuit structure, or a coreless circuit structure.

In the aforementioned electronic package, the present disclosure further comprises a first electronic element disposed on the first side of the carrier and electrically connected to the circuit layer. Moreover, the present disclosure further comprises a packaging layer formed on the first side of the carrier and covering the first electronic element.

In the aforementioned electronic package, the metal structure is contact-bonded to the circuit layer.

In the aforementioned electronic package, the metal structure is a single metal layer or a combination of a plurality of metal layers stacked on each other.

In the aforementioned electronic package, the conductive element protrudes from the opening.

In the aforementioned electronic package, the present disclosure further comprises a conductor formed on the circuit layer, wherein the conductor is located between the conductive element and the circuit layer.

In the aforementioned electronic package, the circuit layer has a circuit body and an electrical contact pad connected to the circuit body and corresponding to the opening for bonding with the metal structure, and wherein a thickness of the electrical contact pad is greater than a thickness of the circuit body.

In the aforementioned electronic package, a plurality of the conductive elements stacked on each other are formed on the circuit layer. For example, the metal structure is disposed between each of the conductive elements.

In the aforementioned electronic package, the conductive element is free from protruding from the opening. For example, the conductive element is lower than the opening and recessed into the encapsulation layer.

In the aforementioned electronic package, the encapsulation layer is formed on a part of a surface of the second side of the carrier, and other parts of the surface of the second side of the carrier are exposed from the encapsulation layer, such that the other parts of the surface of the second side of the carrier are configured with electronic accessories.

In the aforementioned electronic package, the first side of the carrier is formed with a conductive element electrically connected to the circuit layer.

In the aforementioned electronic package, the conductive element is in contact with the entire metal structure in the opening.

In the aforementioned electronic package, the metal structure is grounded to the circuit layer and extends onto the encapsulation layer to cover the second electronic element.

As can be understood from the above, in the electronic package according to the present disclosure, since the metal structure is in contact with and bonded on the wall surface of the opening, the conductive element can be tightly attached onto the metal structure, so that no gap is formed between the conductive element and the wall surface of the opening. Therefore, compared with the prior art, the electronic package of the present disclosure can reduce the DCR of the conductive element, so as to effectively improve the electrical (or telecommunication) performance.

Furthermore, since the conductive element is tightly attached onto the metal structure, the problem of ball dropping of the conductive element can be avoided, such that the reliability of the electronic package can be improved.

### BRIEF DESCRIPTION OF THE DRAWINGS

FIG. 1 is a schematic cross-sectional view of a conventional semiconductor package.

FIG. 2A to FIG. 2D are schematic cross-sectional views illustrating a method of manufacturing an electronic package according to a first embodiment of the present disclosure.

FIG. 3A is a schematic partial cross-sectional view of an electronic package according to a second embodiment of the present disclosure.

FIG. 3B is a schematic partial cross-sectional view showing another aspect of FIG. 3A.

FIG. 4 is a schematic partial cross-sectional view of an electronic package according to a third embodiment of the present disclosure.

FIG. 5A is a schematic cross-sectional view of an electronic package according to a fourth embodiment of the present disclosure.

FIG. 5B is a schematic cross-sectional view of an electronic package according to a fifth embodiment of the present disclosure.

FIG. 5C is a schematic cross-sectional view showing another aspect of FIG. 5B.

FIG. 6 is a schematic cross-sectional view of an electronic package according to a sixth embodiment of the present disclosure.

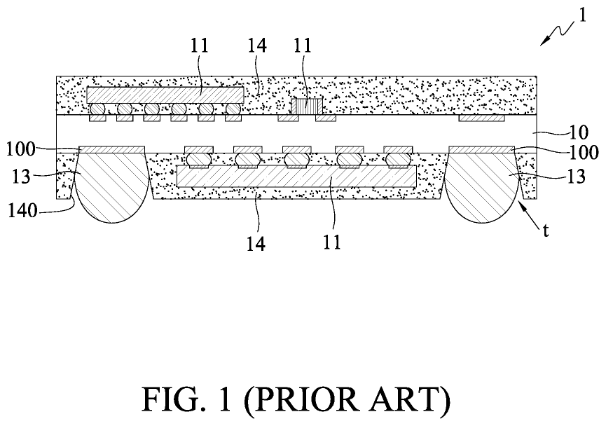

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes, or adjustments to the structures, ratios, or sizes are construed as falling within the scope covered by the technical contents disclosed herein. Meanwhile, terms such as “above,” “on,” “first,” “second,” “a,” “one,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

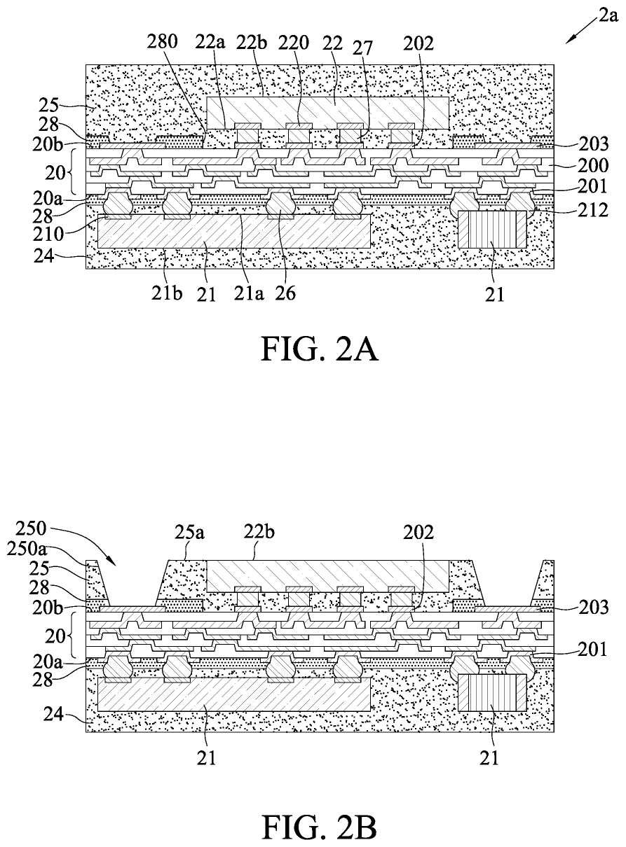

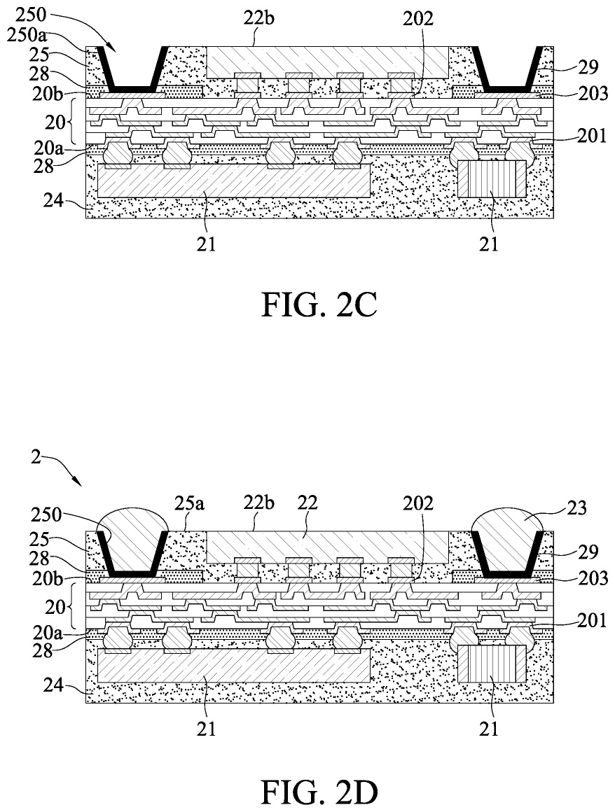

FIG. 2A to FIG. 2D are schematic cross-sectional views illustrating a method of manufacturing an electronic package 2 according to a first embodiment of the present disclosure. As shown in FIG. 2A, an electronic module 2a is provided and comprises a carrier 20, at least one first electronic element 21 disposed on the carrier 20, at least one second electronic element 22 disposed on the carrier 20, a packaging layer 24 covering the first electronic element 21, and an encapsulation layer 25 covering the second electronic element 22.

In an embodiment, the electronic module 2a can be manufactured in various ways, and is not limited to the above.

The carrier 20 is a substrate structure and has a first side 20a and a second side 20b opposing the first side 20a.

In an embodiment, the carrier 20 is a packaging substrate with a core layer and a circuit structure, or a coreless circuit structure, and the carrier 20 comprises at least one dielectric layer 200 and circuit layers 201, 202, 203 bonded with the dielectric layer 200. For example, a manufacturing method of a redistribution layer (RDL) is used to form a coreless circuit structure, wherein the material forming the circuit layers 201, 202, 203 is copper, and the material forming the dielectric layer 200 is dielectric material such as polybenzoxazole (PBO), polyimide (PI), prepreg (PP), etc. It should be understood that the carrier 20 may also be other types of carrier unit capable of carrying electronic elements (such as chips), such as a silicon interposer, and is not limited to the above.

The first electronic element 21 is an active element, a passive element, or a combination of the active element and the passive element, wherein the active element may be a semiconductor chip, and the passive element may be a resistor, a capacitor, or an inductor.

In an embodiment, if the first electronic element 21 is a semiconductor chip, the first electronic element 21 has an active surface 21a and an inactive surface 21b opposing the active surface 21a. The active surface 21a is provided with a plurality of electrode pads 210, which are electrically connected to the circuit layer 201 by a plurality of conductive bumps 26 in a flip-chip manner; alternatively, the first electronic element 21 can also be electrically connected to the circuit layer 201 by a plurality of bonding wires (not shown) in a wire-bonding manner; or, the first electronic element 21 can be in direct contact with the circuit layer 201. If the first electronic element 21 is a passive element, the first electronic element 21 can be electrically connected to the circuit layer 201 by conductive bumps 212. However, the manner of electrically connecting the first electronic element 21 to the circuit layer 201 is not limited to the above.

The packaging layer 24 is formed on the first side 20a of the carrier 20 to cover the first electronic element 21.

In an embodiment, the packaging layer 24 is made of an insulating material, such as polyimide (PI), dry film, encapsulating colloid such as epoxy resin, or molding compound, and the packaging layer 24 can be formed on the first side 20a of the carrier 20 in a manner of lamination or molding.

Moreover, the packaging layer 24 covers the inactive surface 21b of the first electronic element 21. Alternatively, an outer surface of the packaging layer 24 can be flush with the inactive surface 21b of the first electronic element 21 according to requirements, so that the inactive surface 21b of the first electronic element 21 is exposed from the packaging layer 24.

The second electronic element 22 is an active element, a passive element, or a combination of the active element and the passive element, wherein the active element may be a semiconductor chip, and the passive element may be a resistor, a capacitor, or an inductor.

In an embodiment, the second electronic element 22 is a semiconductor chip and has an active surface 22a and an inactive surface 22b opposing the active surface 22a, and the active surface 22a has a plurality of electrode pads 220, so that the electrode pads 220 of the second electronic element 22 are electrically connected to the circuit layer 202 via a plurality of conductive bumps 27 in a flip-chip manner; alternatively, the second electronic element 22 can also be electrically connected to the circuit layer 202 via a plurality of bonding wires (not shown) in a wire-bonding manner; or, the second electronic element 22 can be in direct contact with the circuit layer 202. However, the manner of electrically connecting the second electronic element 22 to the circuit layer 202 is not limited to the above.

Moreover, a non-metallic material such as a solder-resist layer (e.g., green paint), an underfill, or a combination of the solder-resist layer and the underfill can be formed on the second side 20b of the carrier 20 as a protection layer 28, and then part of the protection layer 28 is removed to form an opening 280, so that the opening 280 exposes part of the circuit layer 202 of the second side 20b of the carrier 20, and then the second electronic element 22 is arranged in the opening 280, so that the second electronic element 22 is electrically connected to the circuit layer 202. Alternatively, the protection layer 28 may be directly formed on the circuit layer 202 of the second side 20b of the carrier 20 in a manner of patterning and molding, and part of the second side 20b of the carrier 20 is exposed from the protection layer 28. It should be understood that part of the surface of the other circuit layer 203 on the second side 20b of the carrier 20 is exposed from the protection layer 28.

In addition, the active surface 21a of the first electronic element 21 and the active surface 22a of the second electronic element 22 are arranged face to face.

The encapsulation layer 25 is formed on the second side 20b of the carrier 20, so that the encapsulation layer 25 covers the second electronic element 22, the conductive bumps 27 and the protection layer 28.

In an embodiment, the encapsulation layer 25 is made of an insulating material, such as polyimide (PI), dry film, encapsulating colloid such as epoxy resin, or molding compound, and the encapsulation layer 25 may be formed on the second side 20b of the carrier 20 in a manner of lamination or molding, and the material of the encapsulation layer 25 is different from the material of the protection layer 28.

Furthermore, the material of the encapsulation layer 25 and the material of the packaging layer 24 can be the same or different.

Also, the encapsulation layer 25 covers the inactive surface 22b of the second electronic element 22. Alternatively, the outer surface of the encapsulation layer 25 may be flush with the inactive surface 22b of the second electronic element 22 according to requirements, so that the inactive surface 22b of the second electronic element 22 is exposed from the encapsulation layer 25.

As shown in FIG. 2B, a plurality of openings 250 are formed on the encapsulation layer 25 by laser or other methods, so that part of the circuit layer 203 of the second side 20b of the carrier 20 is exposed from the opening 250.

In an embodiment, a portion of the material of the encapsulation layer 25 can be removed by a leveling process (such as grinding) according to requirements, so that a surface 25a of the encapsulation layer 25 can be flush with the inactive surface 22b of the second electronic element 22, such that the inactive surface 22b of the second electronic element 22 is exposed from the encapsulation layer 25.

As shown in FIG. 2C, a metal structure 29 is formed on a wall surface 250a of each of the plurality of openings 250, so that the metal structure 29 is in contact with and bonded on the wall surface 250a of the opening 250.

In an embodiment, the metal structure 29 extends and covers the exposed surface of the circuit layer 203 to contact and bond on the exposed surface of the circuit layer 203, so that the metal structure 29 is bowl-shaped.

Furthermore, the metal structure 29 can be manufactured by sputtering metal layer(s) (e.g., sputter coating) or other methods, so the metal structure 29 can be a single metal layer or a combination of a plurality of metal layers stacked on each other. For example, the metal structure 29 is a combination of a stainless steel layer and a copper layer, or a combination of a titanium layer and a copper layer.

Also, if the metal structure 29 is manufactured in a manner of sputter coating metal layer(s), the metal material will be formed on the surface of the encapsulation layer 25, so a portion of the material of the encapsulation layer 25 and the metal material thereon can be removed by a leveling process, such as grinding, so that the surface 25a of the encapsulation layer 25 may be flush with the inactive surface 22b of the second electronic element 22, and the inactive surface 22b of the second electronic element 22 is exposed from the encapsulation layer 25. Alternatively, the encapsulation layer 25 can also cover the inactive surface 22b of the second electronic element 22 after the leveling process.

It should be understood that the inactive surface 22b of the second electronic element 22 can be exposed from the encapsulation layer 25 during the process of FIG. 2A, FIG. 2B, or FIG. 2C.

As shown in FIG. 2D, a plurality of conductive elements 23 are formed on the metal structures 29 in the plurality of openings 250, so that the openings 250 are filled by the metal structures 29 and the conductive elements 23, and the conductive elements 23 are electrically connected to the circuit layer 203, thereby obtaining the electronic package 2 of the present disclosure.

In an embodiment, the conductive elements 23 are solder balls or other metal bumps, and the conductive elements 23 are electrically connected to the circuit layer 203 by the metal structures 29. For example, the conductive elements 23 are in contact with all the metal structures 29 in the openings 250.

Therefore, the conductive element 23 can be tightly attached onto the metal structure 29 by contacting and bonding the metal structure 29 on the wall surface 250a of the opening 250, so that the opening 250 can be completely filled by the conductive element 23 and the metal structure 29. Therefore, compared with the prior art, no gap will be formed between the conductive element 23 and the wall surface 250a of the opening 250 in the present disclosure, thereby reducing the DCR of the conductive element 23 to effectively improve the electrical (or telecommunication) performance.

Further, since the conductive element 23 is tightly attached onto the metal structure 29, the problem of the conductive element 23 being loose (or even dropped) can be avoided to improve the reliability of the electronic package 2.

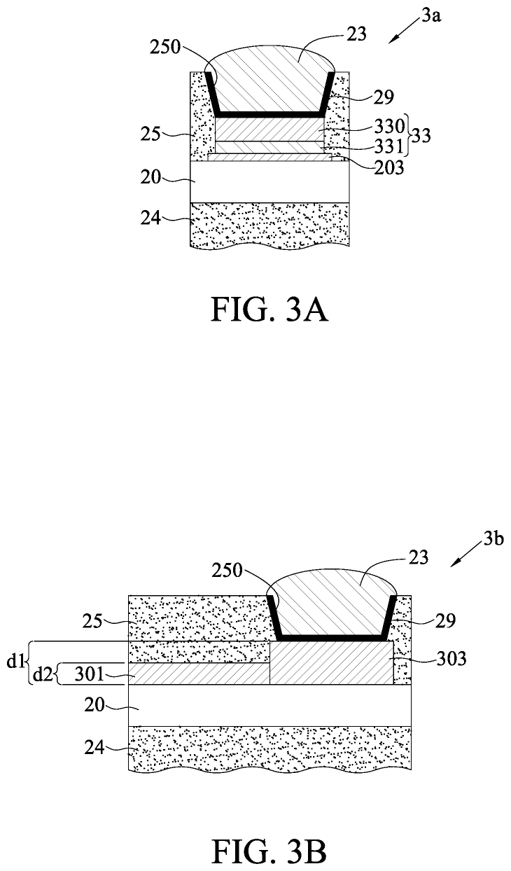

FIG. 3A and FIG. 3B are schematic cross-sectional views showing an electronic package 3a or an electronic package 3b according to a second embodiment of the present disclosure. The difference between the second embodiment and the first embodiment lies in the connection of the conductive element 23, and the other structures are substantially the same, so the similarities will not be repeated below.

As shown in FIG. 3A (part of the dielectric layer and circuit layer are not shown), a conductor 33 is first formed on the circuit layer 203 before forming the encapsulation layer 25, and then the encapsulation layer 25 and the opening 250 thereof are formed, so that the conductor 33 is exposed from the opening 250, and then, the metal structure 29 and the conductive element 23 are formed in the opening 250 to electrically connect the conductor 33, so that the conductor 33 is formed between the metal structure 29 (or the conductive element 23) and the circuit layer 203.

In an embodiment, the conductor 33 comprises a solder layer 331 contacting and bonding the circuit layer 203, and a conductive pillar 330 (such as a copper pillar or other metal pillar) disposed on the solder layer 331 and bonded to the metal structure 29 (or the conductive element 23).

Furthermore, in an embodiment, since the conductor 33 increases the thickness above the circuit layer 203 to reduce the depth of the opening 250, the amount of material for the encapsulation layer 25 to be removed by laser may be reduced, and thus shortening the manufacturing time to reduce the production costs.

Also, since the depth of the opening 250 is reduced, the solder amount of the conductive element 23 can be reduced to increase the proportion of the overall conductive pillar 330, and since the conductivity of the copper material (such as the conductive pillar 330) is greater than the conductivity of the tin material (such as the solder layer 331 and the conductive element 23), the DCR of the overall conductive structure (the conductor 33 and the conductive element 23) in the encapsulation layer 25 in an embodiment therefore may be reduced.

In addition, during the manufacturing of the electronic package 3a, since the conductor 33 is disposed on the circuit layer 203 first and then the opening 250 is formed, it is possible to prevent the laser from directly hitting the circuit layer 203 when burning the encapsulation layer 25, thereby avoiding the problem of destroying the circuit layer 203.

It should be understood that the circuit layer has a circuit body 301 and an electrical contact pad 303 connected to the circuit body 301 and corresponding to the opening 250 to bond the metal structure 29 (or the conductive element 23), as shown in FIG. 3B (part of the dielectric layer and part of the circuit layer are not shown), so a thickness d1 of the electrical contact pad 303 (corresponding to the opening 250) of the circuit layer can also be directly thickened, such that the thickness d1 of the electrical contact pad 303 is greater than a thickness d2 of the circuit body 301, and thus the depth of the opening 250 can be reduced, and the solder amount of the conductive element 23 can be reduced, so as to reduce the manufacturing cost and the DCR of the overall conductive structure in the encapsulation layer 25.

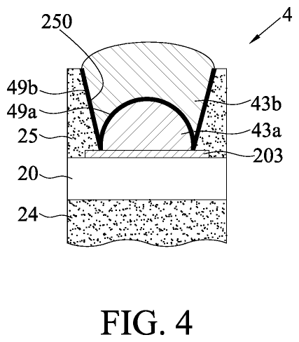

FIG. 4 is a schematic cross-sectional view of an electronic package 4 according to a third embodiment of the present disclosure. The difference between the third embodiment and the second embodiment lies in the design of the thickening structure, and the other structures are substantially the same, so the similarities will not be repeated below.

As shown in FIG. 4 (part of the dielectric layer and part of the circuit layer are not shown), a plurality of conductive elements 43a, 43b stacked on each other are formed on the circuit layer 203, and a metal structure 49a is formed between the conductive element 43a and the conductive element 43b.

In an embodiment, the conductive element 43a may be formed on the circuit layer 203 first, and then the conductive element 43a is covered by the metal structure 49a, and then the encapsulation layer 25 and the opening 250 of the encapsulation layer 25 are formed, so that the metal structure 49a is exposed from the opening 250, and another metal structure 49b is formed on the wall surface 250a of the opening 250, so as to contact and bond another conductive element 43b to the metal structures 49a, 49b. It should be understood that there are many ways to manufacture the conductive elements 43a, 43b and the metal structures 49a, 49b, and the present disclosure is not limited to the above.

Therefore, the conductive elements 43a, 43b can be tightly attached onto the metal structures 49a, 49b by contacting and bonding the metal structure 49b on the wall surface 250a of the opening 250, so that the opening 250 can be completely filled by the conductive element 43b and the metal structures 49a, 49b. Therefore, compared with the prior art, no gap will be formed between the conductive element 43b and the wall surface 250a of the opening 250 in the present disclosure, thereby reducing the DCR of the conductive elements 43a, 43b to effectively improve the electrical (or telecommunication) performance.

Further, since the conductive elements 43a, 43b are tightly attached onto the metal structures 49a, 49b, the problem of the conductive elements 43a, 43b being loose (or even dropped) can be avoided to improve the reliability of the electronic package 4.

Furthermore, in an embodiment, since the conductive element 43a and the metal structure 49a increase the thickness above the circuit layer 203 to reduce the depth of the opening 250, the amount of material for the encapsulation layer 25 to be removed by laser may be reduced, and thus shortening the manufacturing time to reduce the production costs.

Also, in an embodiment, the metal structure 49a is formed between the conductive element 43a and the conductive element 43b to reduce the amount of solder in the opening 250, thereby increasing the proportion of the metal structures 49a, 49b, so the embodiment can further reduce the DCR of the conductive elements 43a, 43b.

In addition, during the manufacturing of the electronic package 4, since the conductive element 43a and the metal structure 49a are disposed on the circuit layer 203 first and then the opening 250 is formed, it is possible to prevent the laser from directly hitting the circuit layer 203 when burning the encapsulation layer 25, thereby avoiding the problem of destroying the circuit layer 203.

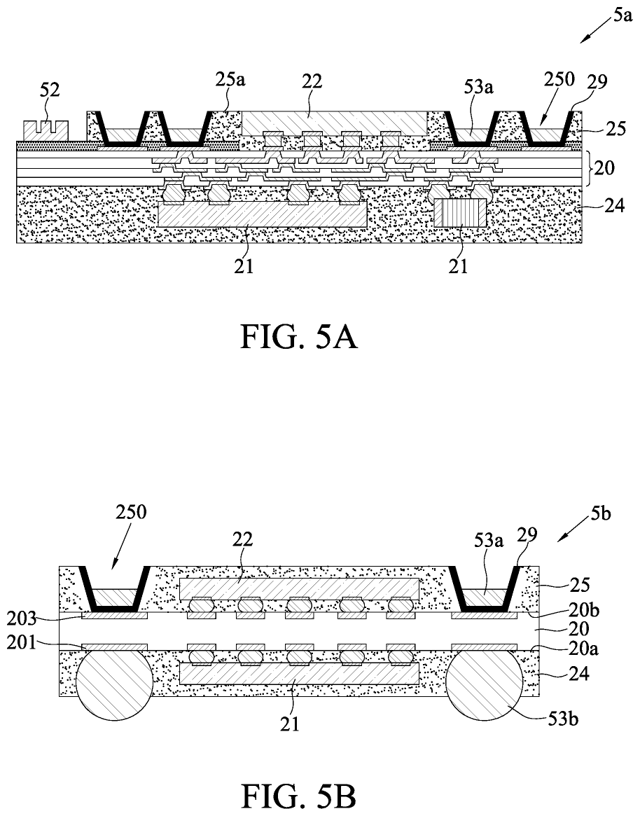

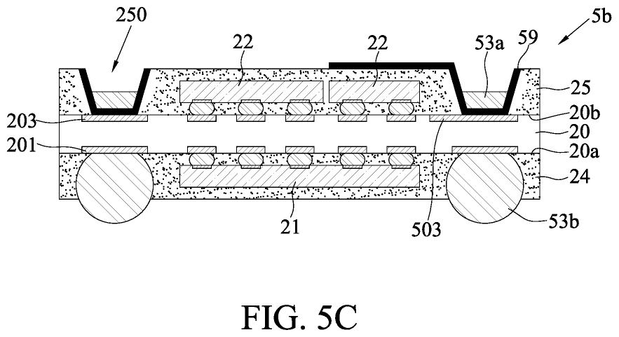

FIG. 5A is a schematic cross-sectional view of an electronic package 5a according to a fourth embodiment of the present disclosure. The difference between the fourth embodiment and the first embodiment lies in the shape of a conductive element 53a, and the other structures are substantially the same, so the similarities will not be repeated below.

As shown in FIG. 5A, a small amount of solder material is formed on the metal structure 29 in the opening 250 as the conductive element 53a, so that the conductive element 53a does not protrude from the opening 250.

In an embodiment, the conductive element 53a is lower than the opening 250 and recessed into the encapsulation layer 25.

Furthermore, the carrier 20 can also be widened so that the encapsulation layer 25 is formed on a part of the surface of the second side 20b of the carrier 20, while other parts of the surface of the second side 20b of the carrier 20 are exposed from the encapsulation layer 25 to be arranged with an electronic accessory such as a connector 52.

Therefore, the conductive element 53a can be tightly attached onto the metal structure 29 by contacting and bonding the metal structure 29 on the wall surface 250a of the opening 250, so that no gap will be formed between the conductive element 53a and the opening 250. Therefore, compared with the prior art, the electronic package 5a of the present disclosure can reduce the DCR of the conductive element 53a, so as to effectively improve the electrical (or telecommunication) performance.

Further, since the conductive element 53a is tightly attached onto the metal structure 29, the problem of the conductive element 53a being loose (or even dropped) can be avoided to improve the reliability of the electronic package 5a.

Moreover, the encapsulation layer 25 is in the shape of a concave portion at the conductive element 53a by the design of the conductive element 53a recessed into the encapsulation layer 25, so that other electronic devices (not shown) can be easily positioned and connected onto the conductive element 53a in the subsequent manufacturing process.

Also, since the conductive element 53a is recessed into the encapsulation layer 25, the amount of the solder material of the conductive element 53a will not be too much, so the thickness of the encapsulation layer 25 does not need to be too thick, so as to facilitate thinning the electronic package 5a.

In addition, since the conductive element 53a is recessed into the encapsulation layer 25, the conductive element 53a will not channel tin when the conductive element 53a is connected to other electronic devices. That is, the solder material of the conductive element 53a will not spread to other areas, so as to avoid the problem of short circuit caused by the bridge between two adjacent conductive elements 53a.

FIG. 5B is a schematic cross-sectional view of an electronic package 5b according to a fifth embodiment of the present disclosure. The difference between the fifth embodiment and the fourth embodiment lies in the configuration of a conductive element 53b, and the other structures are substantially the same, so the similarities will not be repeated below.

As shown in FIG. 5B, a plurality of the conductive elements 53b (such as solder balls) can also be arranged on the first side 20a of the carrier 20.

In an embodiment, the conductive element 53b is exposed from the packaging layer 24 to externally connect to an electronic device (not shown) such as a circuit board, a package, or other suitable objects (such as a memory). For example, the conductive element 53b protrudes from the packaging layer 24.

Furthermore, the configuration of the conductive element 53b facilitates stacking of external electronic devices to expand product functions.

Also, in another aspect, as shown in FIG. 5C, the circuit layer 201 may have a ground portion 503 contacting a metal structure 59, so that the metal structure 59 is grounded to the circuit layer 201 and extends onto the encapsulation layer 25 to cover the second electronic element 22 for shielding the second electronic element 22.

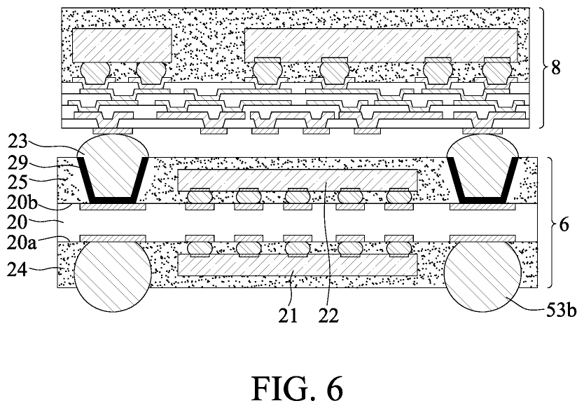

FIG. 6 is a schematic cross-sectional view of an electronic package 6 according to a sixth embodiment of the present disclosure. The difference between the sixth embodiment and the fifth embodiment lies in the design of the conductive element 23, and the other structures are substantially the same, so the similarities will not be repeated below.

As shown in FIG. 6, the electronic package 6 is connected to an electronic device such as another package 8 or a chip by the plurality of conductive elements 23.

In an embodiment, the plurality of conductive elements 53b can be externally connected to an electronic device (not shown) such as a circuit board, a package, or other suitable objects (such as memory) to form a multi-layer stacked package structure.

In view of the above, in the electronic package of the present disclosure, since the metal structure is in contact with and bonded on the wall surface of the opening of the encapsulation layer, the conductive element can be tightly attached onto the metal structure, so that there is no gap formed between the conductive element and the wall surface of the opening. Therefore, the electronic package of the present disclosure can reduce the DCR of the conductive element, so as to effectively improve the electrical (or telecommunication) performance.

Furthermore, since the conductive element is tightly attached onto the metal structure, the problem of ball dropping of the conductive element can be avoided, such that the reliability of the electronic package can be improved.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier having a circuit layer, a first side and a second side opposing the first side;
a second electronic element disposed on the second side of the carrier and electrically connected to the circuit layer;
an encapsulation layer formed on the second side of the carrier and covering the second electronic element, wherein the encapsulation layer has at least one opening exposing part of the circuit layer;
a metal structure contact-bonded on a wall surface of the opening; and
a conductive element formed on the metal structure and electrically connected to the circuit layer.

2. The electronic package of claim 1, wherein the carrier is a packaging substrate with a core layer and a circuit structure, or a coreless circuit structure.

3. The electronic package of claim 1, further comprising a first electronic element disposed on the first side of the carrier and electrically connected to the circuit layer.

4. The electronic package of claim 3, further comprising a packaging layer formed on the first side of the carrier and covering the first electronic element.

5. The electronic package of claim 1, wherein the metal structure is contact-bonded to the circuit layer.

6. The electronic package of claim 1, wherein the metal structure is a single metal layer or a combination of a plurality of metal layers stacked on each other.

7. The electronic package of claim 1, wherein the conductive element protrudes from the opening.

8. The electronic package of claim 1, further comprising a conductor formed on the circuit layer, wherein the conductor is located between the conductive element and the circuit layer.

9. The electronic package of claim 1, wherein the circuit layer has a circuit body and an electrical contact pad connected to the circuit body and corresponding to the opening for bonding with the metal structure, and wherein a thickness of the electrical contact pad is greater than a thickness of the circuit body.

10. The electronic package of claim 1, wherein a plurality of the conductive elements stacked on each other are formed on the circuit layer.

11. The electronic package of claim 10, wherein the metal structure is disposed between each of the conductive elements.

12. The electronic package of claim 1, wherein the conductive element is free from protruding from the opening.

13. The electronic package of claim 12, wherein the conductive element is lower than the opening and recessed into the encapsulation layer.

14. The electronic package of claim 1, wherein the encapsulation layer is formed on a part of a surface of the second side of the carrier, and other parts of the surface of the second side of the carrier are exposed from the encapsulation layer, such that the other parts of the surface of the second side of the carrier are configured with electronic accessories.

15. The electronic package of claim 1, wherein the first side of the carrier is formed with a conductive element electrically connected to the circuit layer.

16. The electronic package of claim 1, wherein the conductive element is in contact with the entire metal structure in the opening.

17. The electronic package of claim 1, wherein the metal structure is grounded to the circuit layer and extends onto the encapsulation layer to cover the second electronic element.
